(19) United States
(12) Patent Application Publication
(10) Pub. No.: US 2024/0128297 A1
(43) Pub. Date: Apr. 18, 2024

(54) DEVICE FOR ACQUIRING A 2D IMAGE AND A DEPTH IMAGE OF A SCENE

(71) Applicant: Commissariat à I'Énergie Atomique et aux Énergies Alternatives, Paris (FR)

(72) Inventors: François Deneuville, Grenoble Cedex 9 (FR); Clémence Jamin, Grenoble Cedex 9 (FR)

(73) Assignee: Commissariat à I'Énergie Atomique et aux Énergies Alternatives, Paris (FR)

(21) Appl. No.: 18/485,181

(22) Filed: Oct. 11, 2023

(30) Foreign Application Priority Data
Oct. 14, 2022 (FR) 2210611

(51) Int. Cl. H01L 27/146

(52) U.S. Cl. CPC H01L 27/14634; H01L 27/14605; H01L 27/14636; H01L 27/14645; H01L 27/1469

(57) ABSTRACT

A device for acquiring a 2D image and a depth image, including: a first sensor formed in and on a first semiconductor substrate and including regions of a material distinct from that of the substrate located in an interconnect stack in line with 2D image pixels of the first r sensor; and adjoining the first sensor, a second sensor formed in and on a second semiconductor substrate and including a plurality of depth pixels located opposite the regions of the first sensor, wherein each region includes a first portion having, in top view, a smaller surface area than that of a second portion, the material of the regions having an optical index greater than or equal to that of the material of the substrate.

### CROSS REFERENCE TO RELATED APPLICATIONS

This application claims priority to French application number 2210611, filed Oct. 14, 2022. The contents of this application is incorporated by herein reference in its entirety.

### Technical Area

The present application relates to the field of image acquisition devices, and, more particularly, to image acquisition devices suitable for acquiring a 2D visible image and a depth image of a scene.

### BACKGROUND ART

Image acquisition devices capable of acquiring depth information have been proposed. For example, time-of-flight (ToF) detectors act to emit a light signal towards a scene, then detect the light signal reflected back by objects in the scene. By calculating the time of flight of the light signal, the distance between the acquisition device and objects in the scene can be estimated. As another example, there are also sensors based on the “structured light” principle. These sensors project a pattern, such as fringes or a grid, onto objects in the scene and capture at least one image of this pattern distorted by the relief of the objects. Processing of the image(s) provides an estimate of the distance between the acquisition device and objects in the scene.

In some applications, it is desirable to be able to simultaneously acquire a visible 2D image and a depth image of the same scene.

While one solution to achieve this objective is to use separate image sensors to capture the 2D image and the depth image, such a solution is not optimal due to the fact that these sensors have different viewpoints of the scene, leading to misalignment between the pixels of the corresponding images. In addition, the use of two sensors increases the size and cost of the device.

Another solution is to integrate 2D image pixels and depth pixels in the same detector array. However, one difficulty is that depth pixels generally have significantly larger dimensions than 2D image pixels and/or significantly higher supply voltages than 2D image pixels, making such integration complex.

The patent applications EP 3503192 and US 2021/0305206 previously filed by the applicant each describe a device for acquiring a 2D image and a depth image of a scene, this device comprising first and second superimposed sensors, the first sensor comprising a plurality of 2D pixels and a plurality of transmissive windows, and the second sensor comprising a plurality of depth pixels arranged respectively opposite the transmissive windows of the first sensor.

It would be desirable to have a device for acquiring a 2D image and a depth image of a scene, which would at least partially overcome one or more of the disadvantages of known devices.

### SUMMARY OF THE INVENTION

To this end, one embodiment provides a device for acquiring a 2D image and a depth image, comprising:
a first sensor formed in and on a first semiconductor substrate having a front face and a rear face, the first sensor comprising a plurality of 2D image pixels, an interconnect stack located on the front face side of the first substrate and in which electrical connection tracks and/or terminals are formed, and regions of a material distinct from that of the substrate located in the interconnect stack in line with 2D image pixels; and
adjoining the first sensor on the front face side of the first substrate, a second sensor formed in and on a second semiconductor substrate and comprising a plurality of depth pixels located opposite the regions of the first sensor,
wherein each region comprises a first portion extending into the interconnect stack from a first face of the interconnect stack facing the first substrate and a second portion extending from a second face of the interconnect stack facing the second substrate, from a second face of the interconnect stack opposite the first substrate, to the first part, the first part having, in top view, a smaller surface area than the second part, the material of the regions having, over a working wavelength range of the second sensor, an optical index greater than or equal to that of the substrate material.

According to one embodiment, the material of the regions also has an absorption coefficient less than or equal to 10⁻³.

In one embodiment, the material of the regions has an optical index greater than or equal to 3.5.

According to one embodiment, the material of the regions is amorphous silicon.

In one embodiment, the electrical connection tracks and/or terminals penetrate the first part of each region.

In one embodiment, each region is bounded laterally, around its entire periphery and over its entire height, by a dielectric material with a refractive index lower than that of the material in the region.

In one embodiment, the region extends over a thickness substantially equal to that of the interconnect stack and is flush with the face of the interconnect stack opposite the first semiconductor substrate.

In one embodiment, the first sensor is a color image sensor, with each 2D image pixel comprising a color filter preferentially transmitting red, green or blue light.

In one embodiment, the regions are located only in line with the 2D image pixels comprising the color filter, which preferentially transmits blue light.

According to an embodiment, the regions are located in line with each 2D image pixel of the sensor.

In one embodiment, the pixels located directly above the regions are grouped together in groups of four adjacent pixels.

In one embodiment, for each group of four adjacent pixels, the region is common to all four pixels.

According to one embodiment, the device further comprises, between each region of the first sensor and the corresponding depth pixel of the second sensor, alternating dielectric layers of distinct refractive indices, forming an anti-reflective stack for light rays traversing said region in the direction of said depth pixel.

In one embodiment, the second sensor comprises, on the rear side of the second semiconductor substrate, an interconnect stack in which electrical connection tracks and/or terminals are formed.

In one embodiment, each depth pixel of the second sensor comprises a SPAD photodiode.

According to one embodiment, each depth pixel of the second sensor comprises several memory zones coupled to a single detection zone, and measures a phase shift between an amplitude-modulated light signal emitted by a light source of the device, and a light signal received by the photodetection zone of the pixel, after reflection from a scene whose image is to be acquired.

In one embodiment, the first and second semiconductor substrates are made of monocrystalline silicon.

One embodiment provides a method of manufacturing a 2D image and depth image acquisition device, the method comprising the following successive steps:
a) forming, in and on a first semiconductor substrate, a first sensor having a front face and a rear face, the first sensor comprising a plurality of 2D image pixels, an interconnect stack located on the front face side of the first substrate and in which electrical connection tracks and/or terminals are formed, and regions of a material distinct from that of the substrate located in the interconnect stack in line with 2D image pixels; and
b) forming, in and on a second semiconductor substrate, a second sensor comprising a plurality of depth pixels located opposite the regions of the first sensor; and c) bonding the second sensor to the first sensor on the front face side of the first substrate, wherein each region comprises a first portion extending into the interconnect stack from a first face of the interconnect stack facing the first substrate and a second portion extending from a second face of the interconnect stack facing the second substrate, from a second face of the interconnect stack opposite the first substrate, to the first part, the first part having, in top view, a smaller surface area than the second part, the material of the regions having, over a working wavelength range of the second sensor, an optical index greater than or equal to that of the substrate material.

According to one embodiment, the method comprises the following successive steps:
forming a first part of the interconnect stack;
forming the first part of the region;
forming a second part of the interconnect stack; and
forming the second part of the region.

In one embodiment, the first and second parts of the region are formed after the interconnect stack has been completed.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a cross-sectional view schematically and partially illustrating an example of a 2D image and depth image acquisition device;

FIG. 2 is a top view schematically and partially illustrating part of the device shown in FIG. 1;

FIG. 3A, FIG. 3B, FIG. 3C, FIG. 3D, FIG. 3E, FIG. 3F, FIG. 3G and FIG. 3H are cross-sectional views schematically illustrating steps in an example of a manufacturing method for a 2D image and depth image acquisition device of the type described in relation to FIG. 1;

FIGS. 4A and 4B are cross-sectional views schematically illustrating steps in a variant of the method described in FIGS. 3A to 3H;

FIG. 5 is a partial schematic top view showing an example of the arrangement of 2D pixels and depth pixels in the device shown in FIG. 1;

FIG. 6 is a partial schematic top view showing a further example of the arrangement of 2D pixels and depth pixels in an example of a 2D image and depth image acquisition device; and

FIG. 7 is a partial schematic top view showing a group of pixels of a 2D image and depth image acquisition device of the type described in relation to FIG. 6.

### DESCRIPTION OF EMBODIMENTS

Like features have been designated by like references in the various figures. In particular, structural and/or functional elements common to the various embodiments may have the same references and may have identical structural, dimensional and material properties.

For the sake of clarity, only those steps and elements that are useful for an understanding of the described embodiments have been illustrated and described in detail. In particular, the design of photodiodes and control circuits for 2D image pixels and depth pixels has not been detailed, as the design of such pixels is within the capabilities of the person skilled in the art from the indications of the present description.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made, unless otherwise specified, to the orientation of the figures.

Unless otherwise specified, the expressions “about”, “approximately”, “substantially” and “on the order of” mean to within 10%, preferably to within 5%.

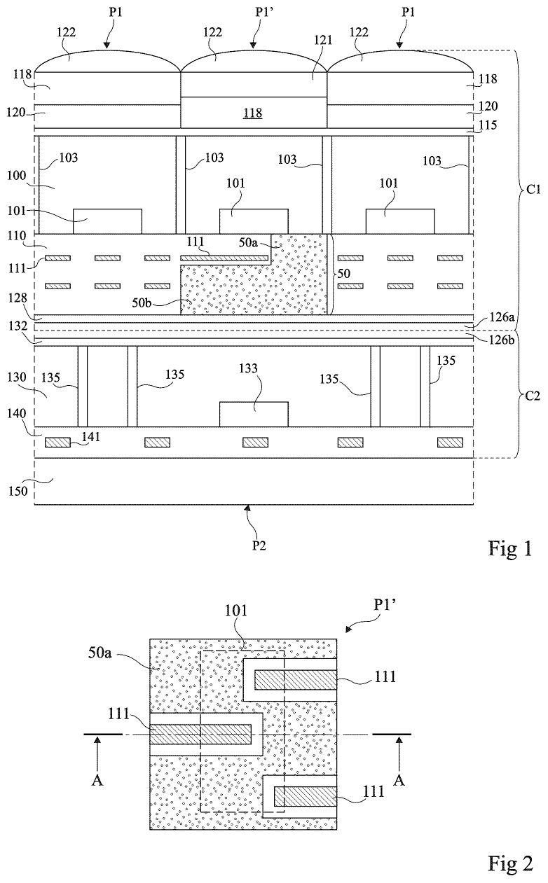

FIG. 1 is a cross-sectional view schematically and partially illustrating an example of a device for acquiring a 2D image and a depth image of a scene.

The device shown in FIG. 1 comprises:
a first sensor C1 formed in and on a first semiconductor substrate 100, for example a monocrystalline silicon substrate, the sensor C1 comprising a plurality of 2D image pixels P1 and P1′ and regions 50 of a material distinct from that of the substrate 100 located in an interconnect stack 110 in line with 2D image pixels P1′; and
a second sensor C2 formed in and on a second semiconductor substrate 130, for example a monocrystalline silicon substrate, the sensor C2 being attached to the front face of the sensor C1 and comprising a plurality of depth pixels P2 located opposite the regions 50 of the sensor C1, each region 50 comprising a first portion 50a extending into the interconnect stack 110 from a first face of the interconnect stack 110 facing the first substrate 100 and a second portion 50b extending, from a second face of the interconnect stack 110 opposite the first substrate 100, to the first portion 50a.

It should be noted that, in the present description, the front face of a substrate is taken to mean the face of the substrate on which an interconnect stack associated with elements formed in the substrate is formed, and the rear face of a substrate is taken to mean the face of the substrate opposite its front face. In the example shown in FIG. 1, the front and rear faces of substrate 100 are its bottom and top faces, respectively.

In practice, the device shown in FIG. 1 is intended for use in combination with a light source emitting in a wavelength range detected by the depth pixels of the sensor C2, for example an infrared source.

For example, in the case of time-of-flight depth measurement, the light source is, for example, a laser source emitting light at a specific wavelength or in a specific wavelength range, preferably a narrow wavelength range, for example a range with a half-value width of less than 3 nm, for example a source with a central emission wavelength of the order of 940 nm. By way of example, the emission wavelength range of the light source lies outside the visible range, for example in the near infrared, e.g. in the 700 nm to 1.5 μm range. In operation, the light signal produced by the light source is emitted towards the scene (e.g. via one or more lenses), in the form of light pulses, e.g. periodic pulses. The return light signal reflected by the scene is picked up by the P2 depth pixels of the sensor C2, so as to measure the time-of-flight of the light signal at different points in the scene and deduce the distance to the acquisition device at different points in the scene. The pixels P1 and P1′ of the sensor C1, for their part, are able to capture visible light emitted by the scene to form a 2D image of the scene.

Alternatively, in the case of structured light depth measurements, for example, the light source can have a central emission wavelength of the order of 940 nm, 1140 nm or 1400 nm.

In the example shown, each pixel P1, P1′ of the sensor C1 comprises a photodiode 101 comprising one or more localized implanted regions formed in the semiconductor substrate 100. In this example, the implanted region(s) of the photodiode 101 are arranged on the front side of the substrate 100. Each pixel P1, P1′ may further comprise one or more additional components (not shown), for example control transistors, formed on the front side of the substrate 100, for example in the substrate 100 and on the front side of the substrate 100. Sensor C1 further comprises interconnect stack 110, consisting of alternating dielectric and conductive layers coating the front face of substrate 100, in which electrical connection tracks and/or terminals 111 are formed connecting pixels P1 and P1′ of sensor C1 to a peripheral control and supply circuit, not shown.

In the example shown, the sensor C1 comprises vertical insulating walls 103 passing through the entire thickness of the 100 substrate and delimiting portions of the substrate corresponding respectively to the various pixels P1 and P1′ of the sensor C1. In particular, the vertical insulating walls 103 fulfil an optical insulation function, and may also have an electrical insulation function. For example, the vertical insulating walls 103 are made of a dielectric material, such as silicon oxide.

According to one aspect of the embodiment shown in FIG. 1, the interconnect stack 110 is interrupted opposite each pixel P1′. Regions 50 are located respectively in the interruption zones of the interconnect stack 110. Each region 50 extends, for example, over substantially the entire thickness of the interconnect stack 110. The thickness of region 50 is for example substantially identical to that of interconnect stack 110, for example between 3 and 15 μm, for example between 5 and 10 μm.

The material of region 50, for example, has an optical index n greater than or equal to that of silicon, e.g. greater than or equal to 3.5 over the working wavelength range of the second sensor C2. In addition, the material of region 50 is, for example, non-absorbent over this wavelength range. More specifically, the material of region 50 has, over the working wavelength range of the second sensor C2, an optical absorption coefficient k less than or equal to 10⁻³, for example less than or equal to 10⁻⁴. The material of region 50 is also chosen to enable filling of the interruption zones of interconnect stack 110. For example, regions 50 are made of amorphous silicon.

Preferably, region 50 is in contact, around its entire periphery and over substantially its entire height, with a material of lower refractive index than the material of region 50, for example silicon oxide when regions 50 are made of amorphous silicon. In this way, light from the rear face of substrate 100 is guided vertically towards the underlying pixel P2. In other words, region 50 acts as a waveguide, enabling the light illuminating the device from the backside of substrate 100 to be transmitted to the pixels P2 with minimal loss.

The thickness of the substrate 100 is, for example, between 2 and 10 μm, for example between 3 and 5 μm.

Each part 50b of region 50 has, for example, when viewed from above, dimensions substantially identical to the dimensions of the pixels P1′ of sensor C1. By way of example, in top view, the largest dimension of each pixel P1′ of the sensor C1 is less than 10 μm, for example less than 5 μm, for example less than 2 μm, for example of the order of 1 μm. By way of example, the pixels P1′ have, in top view, dimensions substantially identical to those of the pixels P1, to within manufacturing dispersions.

In the example shown, the rear face of the substrate 100 is coated with a passivation layer 115, for example a layer of silicon oxide, a layer of hafnium dioxide (HfO₂), a layer of alumina (Al₂O₃), or a stack of several layers of different materials that can perform functions other than passivation alone (anti-reflection, filtering, bonding, etc.), extending over substantially the entire surface of the sensor. By way of example, layer 115 is arranged on and in contact with the rear face of substrate 100.

In the example shown in FIG. 1, the sensor C1 is a 2D color image sensor, i.e. it comprises pixels P1 and P1′ of different types, adapted to measure light intensities in distinct visible wavelength ranges. To this end, each pixel P1, P1′ comprises a color filter 118, for example a colored resin layer, arranged on the backside side of the substrate 100. By way of example, the sensor C1 comprises three types of pixels P1. For example, sensor C1 comprises first pixels P1 called blue pixels, whose color filter 118 preferentially transmits blue light, second pixels P1 called red pixels, whose color filter 118 preferentially transmits red light, and third pixels P1 called green pixels, whose color filter 118 preferentially transmits green light. Alternatively, the sensor C1 comprises only two types of pixels P1, for example red pixels and green pixels, or blue pixels and green pixels, or red pixels and blue pixels. In FIG. 1, the different types of pixels P1 are not differentiated. Furthermore, the sensor C1 comprises, for example, a single type of pixels P1′. By way of example, the color filter 118 of the pixels P1′ preferentially transmits, in addition to the radiation emitted by the light source associated with the device, green, blue or red light, preferably blue light, the sensor C1 comprising, for example, only red and green pixels P1.

Although not detailed in FIG. 1, the layer or stack of layers 115 may comprise an anti-reflective layer or stack of layers made of a material with an optical index between that of the substrate material 100 and that of the color filter material 118, for example tantalum oxide (Ta₂O₅). In addition, the anti-reflective layer or stack of layers can be structured, the structuring varying from pixel to pixel.

In the example shown in FIG. 1, each pixel P1 further comprises an infrared notch filter 120, for example an infrared resin. The filter 120 is adapted, for example, to transmit light at all wavelengths except a range of wavelengths centered on the emission wavelength range of the light source. In this example, filter 120 is arranged on the rear side of substrate 100, for example on and in contact with the side of passivation layer 115 opposite substrate 100, and extends over substantially the entire surface of each pixel P1. The color filter 118 is arranged, for example, on and in contact with the front face of the filter 120. Filter 120 prevents light from the light source reflected by the scene from being detected by pixels P1 and degrading the quality of the 2D image acquired by pixels P1. More generally, filter 120 blocks infrared radiation to improve color rendering of the 2D image.

FIG. 1 shows an example in which, for each pixel P1, filter 120 is interposed between layer 115 and color filter 118. However, this example is not limitative, as the color filter 118 can alternatively be interposed between layer 115 and filter 120.

In the example shown, each pixel P1′ of the sensor C1 is, relative to the pixels P1, devoid of the filter 120. In this example, each pixel P1′ has a region 121 coating the top face of the color filter 118 of pixel P1′ and flush with the top face of the color filters 118 of pixels P1. The regions 121 compensate for a difference in thickness, or height, between the pixels P1 and the pixels P1′ of the sensor C1.

Alternatively, the sensor C1 can be a monochromatic 2D image sensor, in which case filters 118 can be omitted.

Each pixel P1, P1′ of the sensor C1 may further comprise a microlens 122 arranged on the backside of the substrate 100, for example on and in contact with the pixel's color filter 118, adapted to focus incident light onto the photodiode 101 of the underlying pixel P1 or P1′. By way of example, the regions 121 of the pixels P1′ of the sensor C1 are made of the same material as the microlenses 122.

Although not illustrated in FIG. 1, a so-called “dual-band” filter, for example a resin filter and/or an interference filter, adapted to transmit light in the emission wavelength range of the light source and in the wavelength range of the visible spectrum, can be provided on the backside of the substrate 100, for example on the microlenses 122. More precisely, the dual-band filter is, for example, adapted to transmit light in a first, relatively narrow wavelength band centered on the emission wavelength range of the system light source, for example a wavelength range with a half-height width value of less than 30 nm, for example less than 20 nm, for example less than 10 nm, and in a second wavelength band between 400 and 650 nm. The dual-band filter prevents or limits the photo-generation of electrical charges in the photodiode of the underlying pixel P2 under the effect of light radiation not originating from the system's light source. The dual-band filter is for example external to the sensor.

In this example, sensor C1 is bonded to sensor C2 by molecular bonding. For this purpose, sensor C1 comprises a layer 126a, for example made of silicon oxide, located on the side facing the front of substrate 100. In addition, sensor C2 comprises a layer 126b of the same nature as layer 126a, for example made of silicon oxide, located on the side facing the rear of substrate 130. The side of layer 126a facing away from substrate 100 is brought into contact with the side of layer 126b facing away from substrate 130, so as to achieve molecular bonding of sensor C2 to sensor C1. By way of example, layer 126a, respectively 126b, extends continuously over substantially the entire surface of sensor C1, respectively C2.

In the illustrated example, the sensor C1 further comprises, on the front side of the substrate 100, between the interconnect stack 110 and layer 126a, a layer 128 of a material with a different refractive index from that of layers 126a and 126b, for example a material with a higher refractive index than that of layers 126a and 126b, such as silicon nitride. By way of example, layer 128 extends continuously over substantially the entire surface of sensor C1. Layer 126a, for example, is in contact with layer 128 on its side facing the substrate 100.

Furthermore, in this example, the sensor C2 also comprises, on the side of the rear face of the substrate 130, between the substrate 130 and layer 126b, a layer 132 of a material with a refractive index different from that of layers 126a and 126b, for example a layer of the same material as layer 128. Layer 132 has, for example, a passivation function and an anti-reflective function. Layer 132 is for example identical or similar to layer 115. Layer 132 is, for example, a layer of alumina or tantalum oxide, or a stack of several layers of these materials, and the layer or stack of layers can also be structured. By way of example, layer 132 extends continuously over substantially the entire surface of sensor C2. Layer 126b, for example, is in contact with layer 132 on its side facing the substrate 130.

Although not illustrated in FIG. 1, High Quantum Efficiency (HQE) diffraction structures can be provided in the substrate 130.

In this example, the stack of layers 128-126a-126b-132 forms an anti-reflective stack favoring the passage of light from each pixel P1′ to the photosensitive region of the underlying pixel P2. The thickness of layers 128, 126a, 126b, 132 can be chosen as a function of the emission wavelength of the light source, so as to favor the anti-reflective function of the stack at the emission wavelength of the light source, for example so that the reflection coefficient of the stack at the emission wavelength of the light source is less than 6%. As a non-limiting example, for an operating wavelength of the light source of 940 nm and in the case where layer 128 is made of silicon nitride, layer 132 is analogous to layer 115 and layers 126a and 126b are made of silicon oxide, layers 128 and 132 may each have a thickness of the order of 119 nm, and the sum of the thicknesses of layers 126a and 126b may be of the order of 200 nm.

Each pixel P2 of sensor C2 comprises a photodiode 133 formed in substrate 130, opposite sensor C1 region 50. The photodiode 133 comprises one or more localized semiconductor regions formed in the semiconductor substrate 130. For example, each photodiode 133 comprises a photosensitive region, preferably made of silicon if the light source has a central emission wavelength of the order of 940 nm. Alternatively, the photosensitive region of each photodiode 133 may be based on gallium-indium arsenide (InGaAs), germanium (Ge) or at least one organic semiconductor material, such as a polymer. The photosensitive region of each photodiode 133 may comprise quantum dots, for example comprising semiconductor nanocrystals.

The P2 depth pixel can be produced using any technology suitable for distance measurement. For example, the photodiode 133 of pixel P2 may be a SPAD (Single Photon Avalanche Diode) or a photodiode suitable for distance measurement using structured light. Alternatively, the pixel P2 can be of the “lock-in” type, as described in French patent applications No. 16/62341 and No. 16/62340 previously filed by the applicant, i.e. a pixel comprising several memory zones coupled to a single detection zone, and enabling measurement of a phase shift between an amplitude-modulated light signal emitted by the light source and a light signal received by the photodetection zone of the pixel, after reflection from the scene.

Each pixel P2 may further comprise one or more additional components (not shown), for example control transistors, formed on the front side of the substrate 130, for example in the substrate 130 and on the front side of the substrate 130. The sensor C2 further comprises an interconnect stack 140, consisting of alternating dielectric and conductive layers coating the front face of the substrate 130, in which electrical connection tracks and/or terminals 141 are formed connecting the sensor pixels P2 to a peripheral control and supply circuit, not shown.

In the example shown, in each pixel P2 of the sensor C2, the pixel's photodiode 133 is completely surrounded by a vertical insulating wall 135 passing through the substrate 130 over its entire thickness. In particular, wall 135 performs an optical insulation function, and may also have an electrical insulation function. For example, vertical insulating wall 135 is made of a dielectric material, such as silicon oxide. Alternatively, the vertical insulating wall 135 is a multilayer wall comprising an inner layer of a dielectric material, e.g. silicon oxide, one or more intermediate layers comprising at least one metal layer, and an outer layer of a dielectric material, e.g. silicon oxide.

In the example shown, the lateral dimensions of the detection zones of pixels P2 (delimited by walls 135) are greater than the lateral dimensions of the detection zones of pixels P1′ (delimited by walls 103), which makes it possible to relax alignment constraints when assembling sensors C1 and C2. By way of example, the 2D image pixels P1 and P1′ of sensor C1 have a pitch of less than 2 μm, for example of the order of 1 μm, and the depth pixels P2 of sensor C2 have a pitch of less than 4 μm, for example substantially equal to twice the pitch of the 2D image pixels P1 and P1′, for example of the order of 2 μm. However, the embodiments described are not limited to this particular case. Alternatively, the lateral dimensions of the detection zones of the pixels P2 are substantially identical to those of the pixels P1′. In this case, the vertical isolation wall 135 of pixel P2 may be located substantially in line with the vertical isolation wall 103 surrounding the detection zone of the overlying pixel P1′.

The walls 103 and 135, together with the vertical guidance through the region 50, limit the risk of light rays received by a pixel P1 adjacent to pixel P1′ activating the photodiode of the corresponding pixel P2, which could lead to an erroneous depth measurement.

Although not illustrated in FIG. 1, the sensor C2 may also, alternatively, comprise a metal screen covering substantially the entire rear face of the substrate 130, with the exception of the portions of the substrate 130 located inside the walls 135 (corresponding to the photodetection zones of the pixels P2). The metal screen is arranged, for example, between the substrate 130 and the dielectric layer 132. Here again, the function of the metal screen is one of optical isolation, designed to prevent light rays received by a pixel P1 adjacent to pixel P1′ from activating the photodiode of the corresponding pixel P2. Alternatively, the metal screen is not continuous but is made up of a plurality of disjointed rings respectively surrounding, in top view, the photodetection zones of the various sensor pixels P2. Advantageously, this limits parasitic reflections of light from the metal screen towards the pixels P1′ of the sensor C1.

The thickness of substrate 130 is, for example, between 5 and 50 μm, for example between 8 and 20 μm.

In the example shown, the sensor C2 is attached by its front face to a supporting substrate 150, for example a silicon substrate. Alternatively, the support substrate 150 can be replaced by an additional control and processing circuit (not shown) formed in and on a third semiconductor substrate, for example as described in connection with FIG. 1 of the above-mentioned EP 3503192 patent application.

An advantage of the device shown in FIG. 1 is that the pixel matrix P1 and P1′ of sensor C1 has no apertures, or transmissive windows, for example such as those in the devices of the aforementioned patent applications EP3503192 and US2021/0305206. This limits, or avoids, a loss of resolution of the sensor C1 despite the presence of the sensor C2.

FIG. 2 is a top view schematically and partially illustrating part of the device shown in FIG. 1. FIG. 1 corresponds, for example, to a sectional view along plane AA in FIG. 2.

More precisely, FIG. 2 illustrates a pixel P1′, in top view. In order not to overload the drawing, the microlens 122, the color filter 118 and the substrate 100 have not been shown in FIG. 2, and the photodiode 101 has been symbolized by a dotted rectangle.

In the example shown, electrical connection tracks and/or terminals 111 of the interconnect stack 110 extend under the photodiode 101 of the pixel P1′. These tracks and/or terminals 111 penetrate inside part 50a of region 50, with part 50a of region 50 surrounding the tracks and/or terminals 111. The tracks and/or terminals 111 are for example electrically insulated from the region 50, for example by silicon oxide coating the flanks of the part 50a of the region 50. In the example shown in FIG. 2, the pixel P1′ comprises three tracks 111, it being understood that, in practice, the pixel P1′ may comprise any number of tracks and/or terminals 111. In this example, the tracks 111 of the pixel P1′ are, for example, connected respectively to the substrate 100, to a transfer gate and to a read node of the pixel P1′, not detailed in FIG. 2.

According to one embodiment, part 50a of region 50 has, in top view, a smaller area than part 50b of region 50, with part 50b of region 50 having, in top view, an area substantially equal to that of the square symbolizing pixel P1′ in FIG. 2. Unlike part 50a of region 50, no connection tracks or terminals 111 of interconnect stack 110 penetrate inside part 50b of region 50. By way of example, the connection tracks and/or terminals 111 of pixel P1′ are arranged so as to maximize the surface area of part 50a of region 50.

Although FIG. 2 shows a case in which pixel P1′ has a substantially square shape when viewed from above, in practice pixel P1′ can have any shape, for example rectangular, hexagonal or circular.

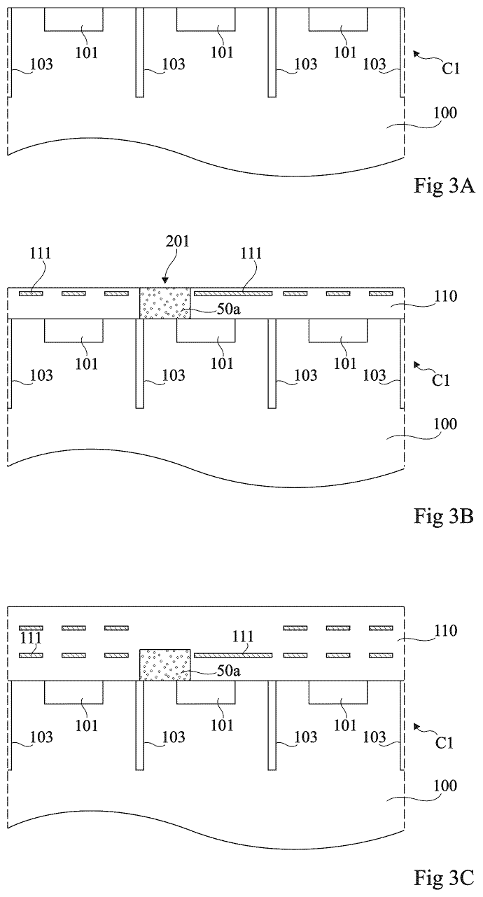

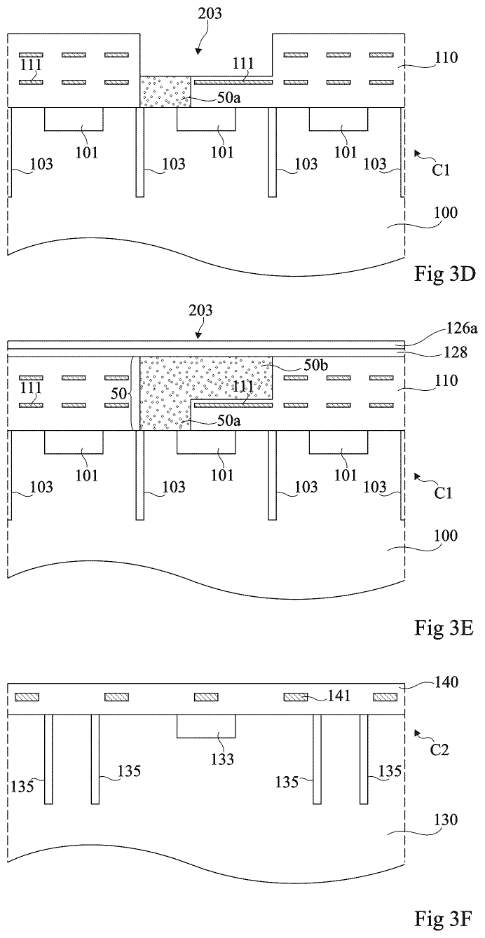

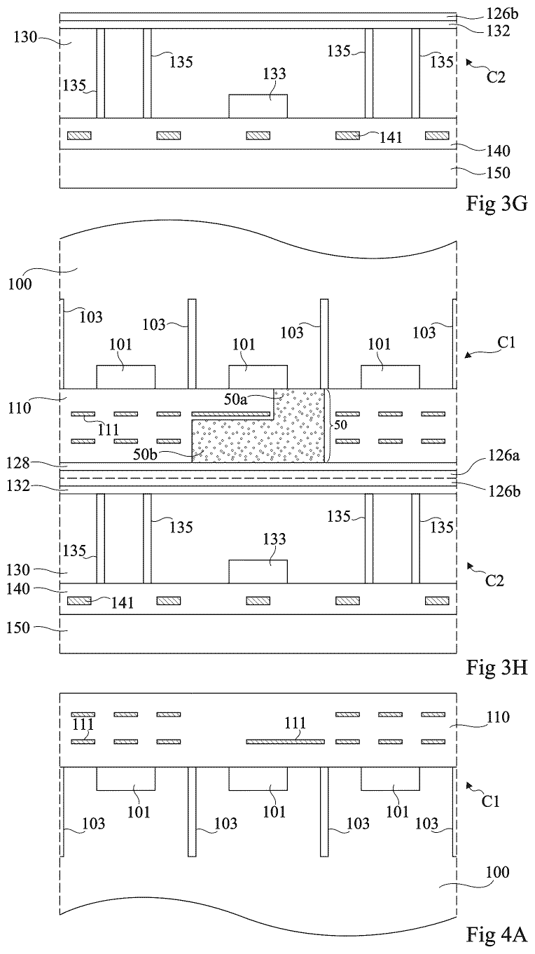

FIG. 3A, FIG. 3B, FIG. 3C, FIG. 3D, FIG. 3E, FIG. 3F, FIG. 3G and FIG. 3H are cross-sectional views schematically illustrating steps in an example of a manufacturing method for a 2D image and depth image acquisition device of the type described in relation to FIG. 1.

More specifically, FIGS. 3A to 3E are cross-sectional views illustrating an example of realization of the sensor C1 of the device shown in FIG. 1, FIGS. 3F and 3G are cross-sectional views illustrating an example of realization of the sensor C2 of the device shown in FIG. 1, and FIG. 3H is a cross-sectional view illustrating a step of bonding the sensor C1 to the sensor C2.

FIG. 3A illustrates a step of manufacturing of the 2D image sensor C1 of the device shown in FIG. 1.

The realization of the sensor C1 starts from a relatively thick semiconductor substrate 100, for example several hundred micrometers thick.

The implanted regions of photodiodes 101 and any control components of pixels P1 and P1′ of the sensor are formed from a first face of substrate 100, namely its top face in the orientation of FIG. 3A. The vertical isolation walls 103 delimiting, in top view, the pixels P1 and P1′ of the sensor are further formed from the top face of the substrate 100.

FIG. 3B illustrates a subsequent step, on the upper surface of substrate 100, of forming part of the interconnect stack 110 of the sensor C1.

In this example, as shown in FIG. 3B, a metal layer of the interconnect stack 110, for example the metal layer of the interconnect stack 110 closest to the top face of the substrate 100, is formed on the top face side of the substrate 100. In the example shown, electrical connection tracks and/or terminals 111 formed in the first metal layer extend opposite the photodetection area of the pixel P1′. In this example, the metal layer of the interconnect stack 110 closest to the substrate 100 is interposed between dielectric layers, not detailed in FIG. 3B, formed during this same step.

FIG. 3B further illustrates a step for forming, from the top face of the structure, an aperture 201 passing vertically through the portion of the interconnect stack 110 previously formed and opening onto the top face of the semiconductor substrate 100. The opening 201 extends over only part of the surface of the photodetection area of the pixel P1′. Aperture 201 is produced, for example, by photolithography followed by etching.

The opening 201 is then filled with material from region 50, forming part 50a of region 50. In the example shown, the region 50 material fills the opening 201 and is flush with the top face of the interconnect stack portion 110 previously made.

FIG. 3C illustrates a subsequent step for finalizing the interconnect stack 110. Specifically, in this step, further metal layers and dielectric layers that do not penetrate into the regions 50 of the interconnect stack 110 are formed on the top side of the structure. In the illustrated example, the material forming the dielectric layers of stack 110 coats the sides and top face of part 50a of region 50 and electrically isolates part 50a from the electrical connection tracks and/or terminals 111.

FIG. 3D illustrates a further step of forming, from the top face of the structure, a further aperture 203 extending vertically, from the face of the interconnect stack 110 opposite the substrate 100, to the part 50a of the region 50. In the example shown, part 50a of region 50 is flush with the bottom of opening 203. Aperture 203 extends laterally over the entire surface of pixel P1′. Aperture 203 is produced, for example, by photolithography followed by etching.

FIG. 3E illustrates subsequent steps for filling the opening 203 with region 50 material, thus forming part 50b of region 50. In the example shown, the region 50 material fills the opening 203 and is flush with the top face of the interconnect stack 110 previously produced.

FIG. 3E further illustrates a subsequent step of depositing the dielectric layer 128, followed by a step of depositing the bonding layer 126a of the sensor C1, on the top face of the interconnect stack 110. In this example, each of the layers 128, 126a extends continuously over the entire surface of the sensor C1. More specifically, in this example, layer 128 is in contact, via its lower face, with the upper face of interconnect stack 110 and region 50. Layer 126a, for its part, is in contact, by its lower face, with the upper face of layer 128.

FIG. 3F illustrates a parallel step for realizing the sensor C2 of the device.

The sensor C2 is based on a relatively thick semiconductor substrate 130, for example several hundred micrometers thick.

The implanted regions of photodiodes 133 and any control components of sensor pixels P2 are formed from a first face of the substrate, namely its top face in the orientation of FIG. 3F. Vertical isolation walls 135 laterally delimiting the pixels P2 are also formed from the top face of substrate 130.

The interconnect stack 140 of the sensor C2 is then formed on the top face of substrate 130.

FIG. 3G illustrates a subsequent step of thinning the substrate 130 of the sensor C2 on the side facing away from the interconnect stack 140.

To achieve this, a support substrate 150 is attached to the side of the interconnect stack 140 opposite the substrate 130. The substrate 130 is then thinned, for example by grinding and/or chemical-mechanical polishing (CMP), on the side facing away from the interconnect stack 140, using the support substrate 150 as a handle.

Note that in FIG. 3G, the orientation of the sensor C2 is reversed with respect to FIG. 3F.

Thinning is interrupted at the face of the vertical insulating walls 135 opposite the interconnect stack 140. In this example, at the end of the thinning step, the walls 135 are flush with the face of the substrate 130 opposite the interconnect stack 140, i.e. the top face of the substrate 130 in the orientation shown in FIG. 3G.

FIG. 3G further illustrates a subsequent step of depositing the passivation layer(s) 132, followed by a step of depositing the bonding layer 126b of the sensor C2, on the upper surface of the thinned substrate 130. In this example, each of the layers 132, 126b extends continuously over the entire surface of the sensor C2. More specifically, in this example, layer 132 is in contact, by its lower face, with the upper face of the thinned substrate 130 and the vertical insulating walls 135. The lower face of layer 126b is in contact with the upper face of layer 132.

FIG. 3H illustrates a subsequent step of transferring the sensor C1 to the sensor C2. The sensor C1 can be turned over and attached to the upper face of the sensor C2, by direct bonding or molecular bonding of the face of the layer 126a opposite the substrate 100 to the face of the layer 126b opposite the substrate 130.

The following steps of the device manufacturing method have not been shown, as these steps are within the capabilities of the person skilled in the art from the indications of the present description. For example, the substrate 100 of the sensor C1 is thinned on the side facing away from the interconnect stack 110, for example by grinding and/or CMP, using the support substrate 150 as a handle. Thinning is interrupted, for example, at the face of the vertical insulating walls 103 opposite the interconnect stack 110, so that, at the end of the thinning step, the walls 103 are flush with the face of the substrate 100 opposite the interconnect stack 110. The top elements of the device shown in FIG. 1, in particular layer 115, filters 120 and 118, and microlenses 122, can then be formed on the side of substrate 100 opposite interconnect stack 110.

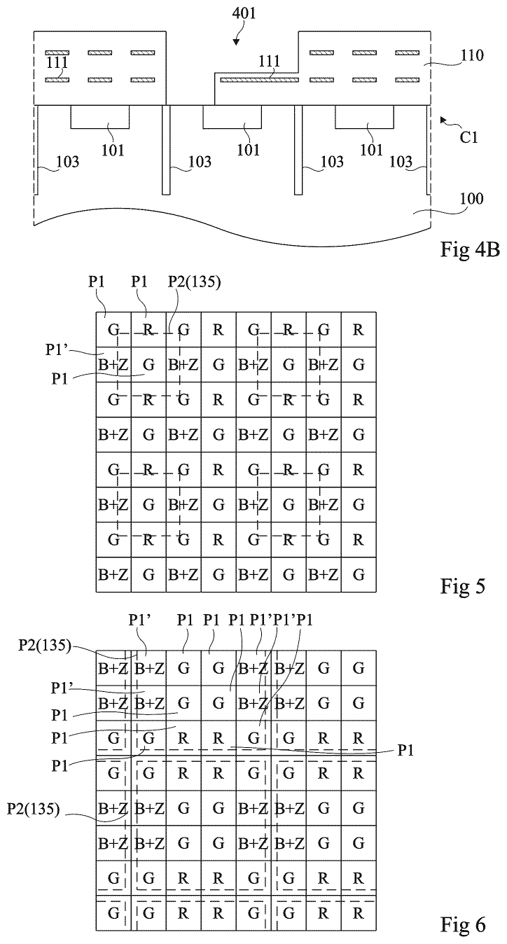

FIG. 4A and FIG. 4B are cross-sectional views schematically illustrating steps in a variant of the method shown in FIGS. 3A to 3H.

More precisely, FIG. 4A illustrates a complete implementation of the interconnect stack 110 of the sensor C1 based on the structure previously described in relation to FIG. 3A.

FIG. 4B illustrates a further step to form a through opening 401 in the interconnect stack 110. Aperture 401, for example, has a shape similar to that of apertures 201 and 203 combined. The opening 401 is obtained, for example, by carrying out the steps of a so-called “double damascene” process. More precisely, a first opening extending over the entire height of the interconnect stack 110 and having a surface area substantially equal to that of the part 50a of the region 50 is for example first formed, for example by photolithography followed by etching. A second aperture extending from the side of the interconnect stack 110 opposite the substrate 100 to a depth less than the first aperture is then formed, for example by photolithography followed by etching, so as to enlarge the upper part of the first aperture to enable the part 50b of the region 50 to be formed subsequently.

The following steps in the variant of the device manufacturing method have not been shown, as these steps are within the capabilities of the person skilled in the art from the indications in the present description. Openings 401 are filled, for example, to form regions 50. A subsequent planarization step can then ensure that the region 50 is flush with the face of the interconnect stack 110 opposite the substrate 100. Manufacture of the FIG. 1 device can then continue as previously described in relation to FIGS. 3E to 3H.

FIG. 5 is a partial schematic top view showing an example of the arrangement of 2D pixels P1 and P1′ and depth pixels P2 in the device shown in FIG. 1.

In this example, sensor C1 is a color sensor comprising only two distinct types of pixels P1, namely red pixels (R) and green pixels (G), and only one type of pixels P1′ (B+Z), namely pixels P1′ whose color filter 118 preferentially transmits, in addition to the infrared radiation emitted by the light source associated with the device, blue light. Alternatively, the sensor C1 may comprise only blue pixels P1 and green pixels P1, with the color filter 118 of the pixels P1′ preferentially transmitting red light in addition to the infrared radiation. Pixels P1 and P1′ are arranged in a matrix in rows and columns, for example in a Bayer pattern. In the example shown, every second pixel in the row direction and every second pixel in the column direction is a pixel P1′ surmounting a pixel P2 of the sensor C2. The vertical isolation wall 135 delimiting the detection zone of each pixel P2 has been shown as a dotted line in FIG. 5. In this example, when viewed from above, the dimensions of the detection zones of pixels P2 of sensor C2 are greater than the dimensions of pixels P1′ of sensor C1. This makes it easier to align the sensor C1 with the sensor C2 when building the device.

Alternatively, the sensor C1 can be a color sensor comprising three distinct types of pixels P1, namely red pixels, blue pixels and green pixels, and a single type of pixels P1′, namely pixels P1′ whose color filter 118 preferentially transmits green light in addition to the infrared radiation emitted by the light source associated with the device.

Alternatively, the sensor C1 is devoid of pixels P1 and comprises only pixels P1′, more precisely three distinct types of pixels P1′, namely pixels P1′ whose color filter 118 preferentially transmits, in addition to the infrared radiation emitted by the light source associated with the device, green light, blue light or red light.

However, the present application is not limited to the examples of combinations of color filter types 118 described. Generally speaking, each pixel P1, P1′ of the sensor C1 can indifferently be associated with a color filter 118 preferentially transmitting blue, green or red light.

In the device shown in FIG. 1, depth pixels P2 can be individually controlled to produce a depth image with a resolution equal to the number of pixels P2 on the sensor C2.

Alternatively, pixels P2 can be coupled in blocks of several neighboring pixels, for example blocks of three by three neighboring pixels P2, to create a photo-multiplier, for example of the SIPM type. In this case, only correlated events within each block are retained. In other words, only events detected simultaneously by several pixels in the block will be retained to build the depth image. The resolution of the depth image is then lower than the number of pixels P2 of the sensor C2, but the noise immunity of the depth image sensor is improved.

It should be noted that, depending on the application in question, the rate at which 2D images are acquired by the sensor C1 may differ from the rate at which depth images are acquired by the sensor C2.

FIG. 6 is a schematic, partial top view showing a further example of the arrangement of 2D pixels P1 and P1′ and depth pixels P2 in an example of an embodiment of a device for acquiring a 2D image and a depth image, for example a device analogous to the device in FIG. 1.

In this example, sensor C1 is a color sensor comprising only two distinct types of pixels P1, namely red pixels (R) and green pixels (G), and only one type of pixels P1′ (B+Z), namely pixels P1′ whose color filter 118 preferentially transmits, in addition to the infrared radiation emitted by the light source associated with the device, blue light. Alternatively, the sensor C1 may comprise only blue pixels P1 and green pixels P1, with the color filter 118 of the pixels P1′ preferentially transmitting red light in addition to the infrared radiation. Pixels P1 and P1′ are arranged in a matrix in rows and columns, for example in a so-called “Quad Bayer” pattern. Compared with the arrangement in FIG. 5, the arrangement in FIG. 6 provides for pixels of each type, from among green pixels P1, red pixels P1, green pixels P1 and pixels P1′, to be grouped into groups of four adjacent pixels. By way of example, each group of four pixels P1 or P1′ of the same type may share the same color filter 118 and the same filter 120. The vertical isolation wall 135 delimiting the detection zone of each pixel P2 has been shown as a dotted line in FIG. 6. In this example, when viewed from above, the dimensions of the detection zones of the pixels P2 of sensor C2 are greater than the dimensions of the groups of four pixels P1′ of sensor C1. This makes it easier to align the sensor C1 with the sensor C2 when building the device.

Alternatively, the sensor C1 can be a color sensor comprising three distinct types of pixels P1, namely red pixels, blue pixels and green pixels, and a single type of pixels P1′, namely pixels P1′ whose color filter 118 preferentially transmits green light in addition to the infrared radiation emitted by the light source associated with the device.

Alternatively, the sensor C1 is devoid of pixels P1 and comprises only pixels P1′, more precisely three distinct types of pixels P1′, namely pixels P1′ whose color filter 118 preferentially transmits, in addition to the infrared radiation emitted by the light source associated with the device, green light, blue light or red light.

In the device shown in FIG. 6, pixels P1 or P1′ in each group of four pixels of the same type can be controlled individually or simultaneously, depending on the intended application. By way of example, the signals from the four pixels P1 or P1′ in each group of pixels of the same type can be cumulated. This allows, for example, a reduction in noise compared with a sensor whose pixels would occupy an area substantially equal to the area occupied by each group of four pixels P1 or P1′ of the same type. Alternatively, in each group of pixels P1 or P1′ of the same type, two pixels can be used to capture a first 2D image during a short exposure time, the other two pixels being used to capture a second 2D image during a long exposure time, greater than that of the first image. The first and second images are captured simultaneously, for example, and then combined to create a High Dynamic Range (HDR) image.

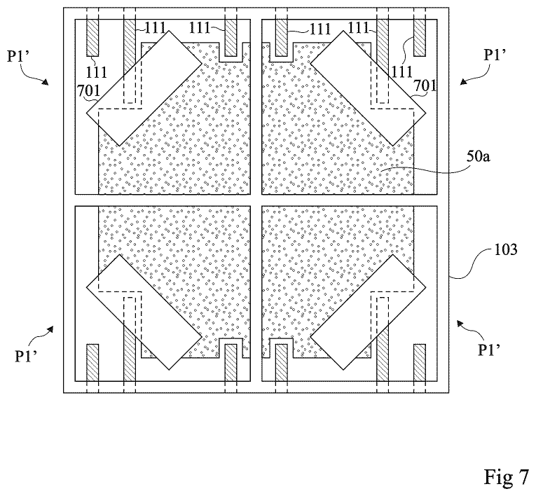

FIG. 7 is a schematic, partial top view of a group of four pixels P1′ of a 2D image and depth image acquisition device of the type described in connection with FIG. 6. In order not to overload the drawing, the microlens 122, color filter 118 and photodiodes 101 have not been shown in FIG. 7. In FIG. 7, the vertical isolation walls 103 delimiting the portions of substrate 100 corresponding respectively to the different pixels P1′ of the group of four pixels P1′ have been shown.

In the illustrated example, electrical connection tracks and/or terminals 111 of the interconnect stack 110 extend beneath the photodiode 101 of each pixel P1′. These tracks and/or terminals 111 penetrate inside part 50a of region 50, with part 50a of region 50 surrounding the tracks and/or terminals 111. In the example shown in FIG. 6, each pixel P1′ comprises three tracks 111 with the understanding that, in practice, the pixel P1′ may comprise any number of tracks and/or terminals 111. In this example, the tracks 111 of each pixel P1′ are, for example, connected respectively to the substrate 100, to a transfer gate 701 and to a read node (not shown) of the pixel P1′. The transfer gates 701 are for example, as illustrated in FIG. 7, arranged at the four corners of the square formed by the group of four pixels P1′. The transfer gates 701 may be planar gates, extending parallel to the front face of the substrate 100, or vertical gates, i.e. extending vertically through the thickness of the substrate 100 from the front face of the substrate 100.

In the example shown, the four pixels P1′ in the group share a common region 50. This has the advantage of limiting diffraction phenomena as light passes through the region 50. It also makes it possible to reduce a contact surface between the regions 50 and the vertical insulating walls 103, with only two side walls of each region 50 in contact with the walls 103, in the example shown in FIG. 7, instead of four side walls, in the example shown in FIG. 5. The result is a reduction in leakage phenomena at the interface between the regions 50 and the walls 103, and hence an increase in the infrared luminous flux transmitted to the second sensor C2.

Various embodiments and variants have been described. The person skilled in the art will understand that certain features of these various embodiments and variants could be combined, and other variants will become apparent to the person skilled in the art. In particular, examples have been described in which the sensor C2 is bonded, by its rear face, to the front face of the sensor C1. Alternatively, the front of the sensor C2 can be bonded to the front of the sensor C1. In this case, openings can be formed in the interconnect stack 140 of the sensor C1, for example, in line with the regions 50. Regions similar to the regions 50 of the sensor C1 could also be formed in the interconnect stack 140 of the sensor C2.

Furthermore, although an example of a method for manufacturing a 2D image and depth image acquisition device comprising regions 50 in line with certain pixels only has been described in relation to FIGS. 3A to 3H, the method is adaptable by the person skilled in the art to a case where the regions 50 are formed in line with each 2D image pixel of the first sensor C1.

Finally, the practical implementation of the described embodiments and variants is within the capabilities of the person skilled in the art on the basis of the functional indications given above. In particular, although devices have been described whose sensor C1 comprises four times as many pixels P1 as pixels P1′, the person skilled in the art is able to realize, from the indications of the present description, devices whose sensor C1 comprises any proportion of pixels P1′ to pixels P1.

1. Device for acquiring a 2D image and a depth image, comprising:
a first sensor formed in and on a first semiconductor substrate having a front face and a rear face, the first sensor comprising a plurality of 2D image pixels, an interconnect stack located on the front face side of the first substrate and in which electrical connection tracks and/or terminals are formed, and regions of a material distinct from that of the substrate located in the interconnect stack in line with 2D image pixels; and
adjoining the first sensor on the front face side of the first substrate, a second sensor formed in and on a second semiconductor substrate and comprising a plurality of depth pixels located opposite the regions of the first sensor,
wherein each region comprises a first portion extending into the interconnect stack from a first face of the interconnect stack facing the first substrate and a second portion extending from a second face of the interconnect stack facing the second substrate, from a second face of the interconnect stack opposite the first substrate, to the first part, the first part having, in top view, a smaller surface area than the second part, the material of the regions having, over a working wavelength range of the second sensor, an optical index greater than or equal to that of the material of the substrate.

2. A device according to claim 1, wherein the material of the regions further has an absorption coefficient less than or equal to 10⁻³.

3. A device according to claim 1, wherein the material of the regions has an optical index greater than or equal to 3.5.

4. A device according to claim 1, wherein the material of the regions is amorphous silicon.

5. A device according to claim 1, wherein the electrical connection tracks and/or terminals penetrate inside the first part of each region.

6. A device according to claim 1, wherein each region is delimited laterally, over its entire periphery and height, by a dielectric material having a refractive index lower than that of the material of the region.

7. A device according to claim 1, wherein the region extends over a thickness substantially equal to that of the interconnect stack and is flush with the face of the interconnect stack opposite the first semiconductor substrate.

8. A device according to claim 1, wherein the first sensor is a color image sensor, each 2D image pixel comprising a color filter preferentially transmitting red, green or blue light.

9. A device according to claim 8, wherein the regions are located solely in line with the 2D image pixels comprising the color filter preferentially transmitting blue light.

10. A device according to claim 8, wherein the regions are located in line with each 2D image pixel of the sensor.

11. A device according to claim 8, in which the pixels located in line with the regions are grouped in groups of four adjacent pixels.

12. A Device according to claim 11, wherein, for each group of four adjacent pixels, the region is common to all four pixels.

13. A device according to claim 1, further comprising, between each region of the first sensor and the corresponding depth pixel of the second sensor, alternating dielectric layers of distinct refractive indices, forming an anti-reflective stack for light rays passing through said region in the direction of said depth pixel.

14. A device according to claim 1, in which the second sensor comprises, on the side facing the rear of the second semiconductor substrate, an interconnect stack in which electrical connection tracks and/or terminals are formed.

15. A device according to claim 1, in which each depth pixel of the second sensor comprises a SPAD-type photodiode.

16. A device according to claim 1, in which each depth pixel of the second sensor comprises several memory zones coupled to the same detection zone, and enables measurement of a phase shift between an amplitude-modulated light signal emitted by a light source of the device and a light signal received by the photodetection zone of the pixel, after reflection on a scene whose image is to be acquired.

17. A device according to claim 1, in which the first and second semiconductor substrates are made of monocrystalline silicon.

18. A method of manufacturing a device for acquiring a 2D image and a depth image, the method comprising the following successive steps:
a) forming, in and on a first semiconductor substrate, a first sensor having a front face and a rear face, the first sensor comprising a plurality of 2D image pixels, an interconnect stack located on the front face side of the first substrate and in which electrical connection tracks and/or terminals are formed, and regions of a material distinct from that of the substrate located in the interconnect stack in line with 2D image pixels; and
b) forming, in and on a second semiconductor substrate, a second sensor comprising a plurality of depth pixels located opposite the regions of the first sensor; and
c) joining the second sensor to the first sensor on the front face side of the first substrate,
wherein each region comprises a first portion extending into the interconnect stack from a first face of the interconnect stack facing the first substrate and a second portion extending, from a second face of the interconnect stack opposite the first substrate, to the first part, the first part having, in top view, a smaller surface area than the second part, the material of the regions having, over a working wavelength range of the second sensor, an optical index greater than or equal to that of the material of the substrate.

19. The method according to claim 18, comprising the following successive steps:
forming a first part of the interconnect stack;
forming the first part of the region;
forming a second portion of the interconnect stack; and
forming the second part of the region.

20. The method according to claim 19, in which the first and second parts of the region are formed after the interconnect stack has been completed.
